(19) United States
(12) Patent Application Publication
(10) Pub. No.: US 2026/0263324 A1
(43) Pub. Date: Sep. 10, 2026

(54) ACUPUNCTURE NEEDLE, SORBING HEAVY AND TOXIC METAL IONS, METHOD FOR PRODUCTION AND APPLICATION

(71) Applicant: Artem Olegovich BAKHMETYEV, Mytishchi (RU)

(72) Inventor: Artem Olegovich BAKHMETYEV, Mytishchi (RU)

(21) Appl. No.: 19/491,408

(22) PCT Filed: Mar. 27, 2024
(86) PCT No.: PCT/RU2024/050066

§ 371 Date: Dec. 9, 2025

(30) Foreign Application Priority Data
Jun. 19, 2023 (RU) 2023116056

(51) Int. Cl. A61H 39/08; B01J 20/06; B01J 20/28; B01J 20/32

(52) U.S. Cl. CPC A61H 39/086; B01J 20/06; B01J 20/28033; B01J 20/3202; B01J 20/3236

(57) ABSTRACT

The group of inventions falls within the field of medical equipment. The method for producing needles with sorption properties by ferric oxide ALD coating on acupuncture needles has been described. The acupuncture needles for reflexotherapy consisting of handle and shaft made of metal material are placed in a reactor, in which vacuum has been created to a pressure value of 10 mbar+0.04 mbar, as well as temperature of 150° C., thereafter ferrocene-carboxylic acid precursor in the form of vapors is delivered to the reactor, then nitrogen is filled into the reactor and degassed to the initial pressure, with the process repeated in pulse mode cycle after cycle until the specified coating thickness is formed. The use ferrocene-carboxylic acid as a precursor for the production of Fe3O4 coating has been described. Acupuncture needles for sorption of heavy and toxic metal ions are presented with a nanofilm coating thickness of Fe3O4 14 nm+0.1 nm, with the nanofilm having the appearance of nano sieves as shown in FIG. 1 b). The use of acupuncture needles for sorption of metal ions has been presented. The technical result is the development of a technically and technologically simpler, and therefore inexpensive way to apply Fe3O4 magnetic separation film on the surface of acupuncture needles, giving them sorption properties. The needles under the present invention enable the sorption of the following heavy and toxic metal ions: cadmium, arsenic, manganese, cesium, aluminium, iron, cobalt, nickel, chromium, mercury, lead, copper, zinc, beryllium, antimony, thallium, bismuth, osmium, tin, molybdenum, zirconium, titanium, vanadium, molybdenum, gallium.

### FIELD OF THE INVENTION

The present solution falls within the field of medicine and medical equipment, in particular acupuncture needles for carrying out the acupuncture procedure that facilitates sorption and removal of heavy and toxic metal particles (ions) from the human body.

### BACKGROUND

The claimed acupuncture needle for reflexotherapy comprises of a handle and a shaft, and the applied part of the shaft is coated with magnetic nanoparticles of ferric oxide Fe₃O₄ and/or γ-Fe₂O₃.

The invention also relates to the method for producing such needles by applying an atomic-layer deposition of ferric oxide coating to the acupuncture needles.

The technical result is to provide wider sorption properties for removing toxic substances, including heavy and toxic metal particles (ions) from the human body by application of magnetic nanoparticle coating, as well as the development of a technically and technologically simpler, and therefore inexpensive method for applying magnetic separation Fe₃O₄ film with a specified thickness to the surface of acupuncture needles. Considering that the resulting modified acupuncture needles have broad sorption properties, including with respect to the following metal ions: cadmium, arsenic, manganese, cesium, aluminium, iron, cobalt, nickel, chromium, mercury, lead, copper, zinc, beryllium, antimony, thallium, bismuth, osmium, molybdenum, zirconium, titanium, vanadium, molybdenum, gallium; the invention can be used both as a traditional acupuncture needle used in acupuncture, and for cleansing the human body of heavy metals and toxins without any side effects to the body. The invented acupuncture needles can be used both for cleansing the body for therapeutic purposes, and for preventive daily use.

From the technical level, RU 2674985C2, 14.12.2018, the method of applying coating to surgical needle is known. It includes the application of silicon coating on a surgical needle, where this needle is installed on the carrier, by immersing the surgical needle in a silicon coating solution by moving the needle in a silicon coating solution bath, with the needle placed on the carrier in such a way that the tip of the needle is directed upwards, removing the needle from the coated bath, directing the air flow to the needle along the path at an angle of about +/−20° to the longitudinal central axis of the distal end section of the needle, so that a sufficient amount of silicon coating solution is retained on the tip section of the needle; and the solidification of the silicon coating, wherein the solution of silicon coating contains polydimethylsiloxane with vinyl-end group, polymethyl siloxane with metal-end group, a binding agent viz. methyl hydro siloxane, a platinum complex with divinyltetramethylidyl dioxane and ethyl cyclohexanol and organic solvents.

The method of ferric oxide coating (II, III) by plasma flame sputtering on metal surfaces is also known from the published work of A. A. KHAFISOV and others Ferromagnetic powder spraying on steel by plasma sprayer with electrolytic cathode, Socio-economic and technical systems: research, design, optimization, 2015, V. 1, N 1 (64), P. 25-33. The essence of this method consists in that gas (argon, nitrogen, air) is passed through an arc (electrode electrolyte and copper nozzle) burning between two electrodes. Due to the high energy of the burning arc, gas atoms lose electrons from their outer shells. As a result, an ion-electron gas or plasma is produced. The temperature of the plasma jet reaches a temperature of 3000-5000° C. The powder material is delivered to the area at the outlet from the nozzle to the plasma jet. As a result, the sprayed-on material is heated to melting, dispersed and applied to the surface of the workpiece. During the spraying process, it is necessary to control the thickness of the sputtered layer, which is 0.1-2 mm for plasma coating.

The disadvantage of this method is that there is a need to control the thickness of the sputtered-metal coating, which for plasma coating is 0.1-2 mm.

From the technical level RU 2761440 C2, 08.12.2021, the method of applying coating to medical devices in contact with tissues, in particular to needles for injection by cleaning and activating the surface of the needles with accelerated ions and further ion-plasma sputtering first with a stream of gaseous accelerated particles containing the organosilicon compound, and then ion-plasma sputtering with a stream of gaseous accelerated particles containing iron (Fe) and/or titanium (Ti) atoms, is also known.

The disadvantage of this method is the application of an additional precoating of an organosilicon compound, which prolongs the duration of the method, and the needles have insufficient adhesive strength.

In addition, from the technical level RU 2717705 C1, 25.03.2020 the application of gaseous flame coating of ferric oxide on needles is known. The size of the Fe₃O₄ nanoparticle coating is between 10 and 100 nm+20%.

The disadvantage of this method is that the granulated composition of the ferric oxide (II, III) powder used must be uniform for application. With a wide particle size range, the quality and adhesion of coatings is significantly impaired.

The closest analog of the presented solution in terms of how to create acupuncture needles with sorption properties is the solution disclosed in RU 2773965 C1, 14.06.2022. The known solution is a method of applying iron oxide coating to acupuncture needles by atomic layer deposition. Acupuncture needles are placed in the reaction chamber, vacuum is created inside the chamber under pressure of 1-5 mbar, a cycle is carried out which includes heating of the acupuncture needles to 220-280° C. temperature, discrete sequential feeding into the reaction zone of vapors of bis-η5-cyclopentadienyl iron II (ferrocene) precursor with temperature of 80-100° C. for 1-3 s with time delay for 1-3 s and oxygen reagent gas under pressure 1-3 bar for 5-7 s with time delay for 1-3 s. After the discharge of the above-mentioned precursor and after the discharge of oxygen, the reactor is blown with nitrogen and degassed to the initial pressure. This cycle is carried out before the formation of the specified coating thickness 4-32 nm with at least 600 cycles. The solution ensures uniform coating, increased sorption properties and adhesive strength of the resulting acupuncture needles.

However, at the technological level there is still a need to provide a method of producing acupuncture needles with sorption properties that will be technologically simpler and therefore cheaper, while allowing the production of needles with standardized parameters, in particular the coating thickness.

The closest analog of the presented solution in terms of acupuncture needles with sorption properties is the solution disclosed in RU 189268 U1, 17.05.2019. The well-known acupuncture needle for reflexotherapy comprises of a handle and a shaft, and the applied part of the shaft is coated with magnetic nanoparticles of ferric oxide Fe₃O₄ and/or γ-Fe₂O₃. The needle provides sorption and removal of heavy metals particles from the human body through the application of magnetic nano-particle coating of iron oxides magnetite (Fe₃O₄) and/or maghemite (γ-Fe₂O₃). However, at the level of technology there is a need for acupuncture needles with enhanced sorption properties.

The acupuncture needles of the present invention have sorption properties with respect to the following metal ions: cadmium, arsenic, manganese, cesium, aluminium, iron, cobalt, nickel, chromium, mercury, lead, copper, zinc, beryllium, antimony, thallium, bismuth, osmium, tin, molybdenum, zirconium, titanium, vanadium, molybdenum, gallium, have a given coating thickness of 14 nm, nanofilm on the needle surface is an analog of nano sieves in which there are areas where negative charge “accumulates” due to concentration of surplus oxygen atoms, as well as the formation in the film of individual domains with magnetic susceptibility by forming crystals from magnetoactive ferric oxide. When the blood containing metal ions enters them, the latter are sorbed.

The method of sorption and removal of heavy metal particles from the human body is known from RU 2717705 C1, 23.03.2020. The acupuncture points are determined for this purpose. At least 15 needles for reflexotherapy are injected into the acupuncture points of the entire body and at least 15 needles for reflexotherapy in the acupuncture points locally in accordance with the affected organs. Acupuncture needles for reflexotherapy are used with a handle and shaft made of metal. At least, the applied part of the shaft is coated with magnetic nanoparticles of magnetic oxide of iron Fe₃O₄ and/or maghemite γ-Fe₂O₃. The needle is removed after 30-90 minutes. The method provides an overall improvement of human health through sorption and removal of heavy metals from blood flow and lymph flow of the body, reducing their concentration in the body.

However, there is a need to expand the spectrum of heavy metals and toxins removed when using the acupuncture needles with sorption properties.

The claimed comprehensive solution resolves the application tasks:

### SUMMARY

The objective of the present invention is to create a unique magnetic separation coating Fe₃O₄ in the form of nano sieves.

The technical result is the development of a technically and technologically simpler, and therefore inexpensive method of applying Fe₃O₄ magnetic separation film to the surface of acupuncture needles, giving them sorption properties.

The objective of the invention is solved, and the technical result is achieved by using a new precursor viz. ferrocene carboxylic acid.

The present invention relates to the method for producing acupuncture needles with sorption properties, having Fe₃O₄ magnetic separation film coating of thickness 14 nm+0.1 nm on the surface. This coating is applied by atomic layer deposition of ferric oxide coating. Acupuncture needles for reflexotherapy consisting of a handle and shaft made of metal material are placed in the reactor, in which vacuum is created to a pressure value of about 10 mbar±0.1 mbar, as well as temperature of 150±0.2° C. Then the ferrocene carboxylic acid precursor is delivered in vapor form to the reactor.

Thereafter the reactor is filled with nitrogen and degassed to the initial pressure with the process repeated in pulse mode cycle after cycle until the given coating thickness is formed.

This method makes it possible to obtain 14 nm±0.1 nm thick needles with Fe₃O₄ magnetic separation film, coated in the form of nano sieves, in which there are areas where negative charge “accumulates” due to concentration of surplus oxygen atoms, as well as the formation in the film of individual domains with magnetic susceptibility by forming crystals from magnetoactive ferric oxide. When they get into the blood containing metal ions, the latter are sorbed by three mechanisms:

By magnetic separation. Those magnetoactive ions (cobalt, nickel, chrome, manganese, iron, copper, titanium, osmium) contained in the biological fluid are attracted to the surface of the film on which the domain structures are formed.

By physical adsorption (heavy metals and semimetals: cadmium, cesium, lead, mercury, chromium, zinc, antimony, arsenic, thallium, zirconium, antimony, zirconium). Due to the Coulomb interaction of the film surface and cation (metal ion), there is a capture of the metal ion from the blood and its retention on the film surface of those metal ion implantation into the film cavity.

Chemical adsorption (copper, zinc, nickel, aluminium, cobalt, beryllium, bismuth, tin, molybdenum, vanadium, gallium, gallium). Through the formation of chemical bonds, analog, chelation. When a bond is formed between ions and oxygen atoms of the film, the bonds are formed that firmly “firmly” hold it on the surface.

Moreover, it is shown that a significant sorption occurs on the modified needles with 14 nm ferric oxide (II, III) coating thickness.

Thus, the invention also relates to acupuncture needles produced by this method and having sorption properties in respect of the following metal ions: cadmium, arsenic, manganese, cesium, aluminium, iron, cobalt, nickel, chrome, mercury, lead, copper, zinc, beryllium, antimony, thallium, bismuth, osmium, tin, molybdenum, zirconium, titanium, vanadium, molybdenum, gallium, and having 14 nm±0.1 nm coating thickness of the specified film.

In addition, since the essential feature to achieve the technical result viz, the production of film in the form of nano sieves, as indicated in FIG. 1 (b), is the use of a new precursor viz. ferrocene-carboxylic acid, the invention also relates to the use of ferrocene carboxylic acid precursor for obtaining Fe₃O₄ film coating.

The specified application is used in the method of the present invention, and therefore both the claimed method and the claimed application are intended for producing (obtaining) the claimed acupuncture needles.

Another invention is the use of the claimed needles for sorption of metal ions.

### DESCRIPTION OF FIGURES

Morphology of the film surface was studied with REM.

FIG. 1-REM image acupuncture needle unmodified (a) acupuncture needle with application of 14 nm ferric oxide 3 (b).

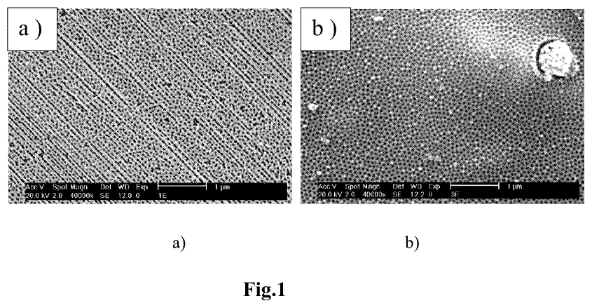

As seen from FIG. 1 (b) a porous Fe₃O₄ film with thickness 14 nm is formed.

### DISCLOSURE OF THE INVENTION

### Examples

Acceptable temperature deviation 0.2° C., acceptable pressure deviation 0.1 mbar (1%).

### Example 1. Production of Acupuncture Needles with Sorption Properties

The acupuncture needles were placed in the reactor, which was pumped out to ~10 mbar, heated to 150° C. The needles in the reactor are heated to a given temperature, then ferrocene carboxylic acid precursor is delivered as vapor to the area where they are located. After the entry of ferrocene-carboxylic acid into the reaction zone, it thermally breaks down according to the following scheme:

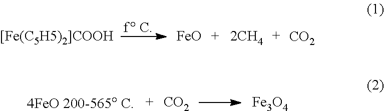

The vapor obtained by evaporating the precursor (η 5-C5N5)2FeCOOH (ferrocene carboxylic acid), heated to 60° C. for 400 ms was fed consecutively. After starting each precursor, the reactor was filled with nitrogen for 1 s and degassed to the initial pressure. The process was repeated in pulse mode cycle after cycle; the time of one cycle was 9 seconds. The number of cycles was 180. As a result, 14 nm thick coating was obtained.

High-tech TFS 200 from Beneq (Finland) was used as the reactor. The abovementioned reactor is a round closed container of diameter 200 mm and height 3 mm. Pressure up to about 10 mbar was created by a pump by creating vacuum inside the reactor to the pressure of the specified value. The heating elements on the outside of the vessel create the given temperature in the reactor.

The invention method has a decrease in temperature compared to using ferrocene, which is due to the decomposition of the ferrocene-carboxylic acid precursor used.

In contrast to the use of ferrocene and oxygen, when using ferrocene-carboxylic acid, oxygen contained in the CO2 molecule, which is formed by the peroxide reaction plays the role of oxygen. Thus, the use of this precursor considerably reduces the process time.

The defining differences of the claimed method, compared to known ones, are:
the substrate is heated to a temperature of 150° C., which makes it possible to use a more volatile ferrocene-carboxylic acid precursor;
the use of ferrocene-carboxylic acid allows the reaction to be conducted without using an external source of oxygen;
the use of an internal source of oxygen makes it possible to make maximum use of ferrocene-carboxylic acid for the formation of the given ferric oxide 3.

### Example 2. Sorption of Mercury Ions

Sorption of mercury ions was carried out by modified acupuncture needles coated with 14 nm ferric oxide (II, III). The given total concentration for mercury ions equal to 3 μg/l was prepared by diluting HCO ions of monovalent and bivalent mercury (50/50) entering in the customer's blood. Next, a 14 nm thick needle was placed in the prepared “blood” solution with a mercury ion concentration of 3 μg/1. After sorption, the ion concentration in the “blood” solution was measured on SHIMADZU AA-7000 atomic absorption spectrophotometer. It was shown that the concentration change was 0.4%, the sorption capacity (H) was 0.45 μg/g.

### Example 3. Sorption of Lead Ions

The test solution with lead ion concentration=2 μg/l was prepared and sorption was made using modified acupuncture needles coated with ferric oxide (II, III) of thickness 14 nm for 1 hour. After sorption, ion concentration in the solution was measured on SHIMADZU AA-7000 atomic absorption spectrophotometer. It is shown that the sorption process takes place at a very low level 0.011%, the sorption capacity (H) was 0.034 μg/g.

### Example 4. Sorption of Cesium Ions

The test solution with cesium ion concentration=2.7 μg/l was prepared and sorption was made using modified acupuncture needles coated with ferric oxide (II, III) of thickness 14 nm for 1 hour. After sorption, ion concentration in the solution was measured on SHIMADZU AA-7000 atomic absorption spectrophotometer. It is shown that the sorption process takes place at a very low level 0.035%, the sorption capacity (H) was 0.11 μg/g.

Thus, compared to the closest analog, the coating application method was simplified; on the one hand, this method allows reduce the temperature in the reactor from 220-280° C. to 150° C. and the precursor feed temperature from 80-100° C. to 60° C., which reduces electricity costs. On the other hand, the use of a new precursor makes it possible to avoid using an external source of oxygen, which also reduces the cost. In this case, the coating of the needles has the appearance of nano sieves as shown in FIG. 1 b).

In comparison with the closest analog, the sorption properties at a comparable coating thickness by mercury ions for needles under the present invention were 0.45 μg/g and in the closest analog 0.32.

1. A method for producing acupuncture needles with Fe₃O₄ coating and sorption properties, wherein the method comprises following steps:
placing acupuncture needles for reflexotherapy, consisting of a handle and a shaft made of metal material, in a reactor in which vacuum is created to a pressure value of 10 mbar±0.1 mbar and a temperature of 150±0.2° C.;
delivering ferrocene-carboxylic acid in vapor form to the reactor;
filling nitrogen into the reactor and degassing the reactor to the initial pressure, wherein with the process repeated in pulse mode cycle after cycle until the specific nanofilm coating thickness of Fe₃O₄ 14 nm±0.1 nm is formed, and the nanofilm has a nano sieve appearance as shown in FIG. 1 b).

2. An acupuncture needle for metal ion sorption, obtained by the method as per claim 1, having Fe₃O₄ nanofilm coating thickness of 14 nm±0.1 nm, wherein the nanofilm has the appearance of nano sieves as shown in FIG. 1 b).

3. An application of acupuncture needle as per claim 2 for sorption of metal ions with a Fe₃O₄ nanofilm coating thickness of 14 nm±0.1 nm, wherein the nanofilm has the appearance of nano sieves as shown in FIG. 1 b).
